(19) United States
(12) Patent Application Publication
(10) Pub. No.: US 2023/0003997 A1
(43) Pub. Date: Jan. 5, 2023

(54) OPTICAL REFLECTOR ELEMENT AND LIGHT CONTROL SYSTEM

(71) Applicant: Panasonic Intellectual Property Management Co., Ltd., Osaka (JP)

(72) Inventors: Kensuke MIHARA, Osaka (JP); Ryouichi TAKAYAMA, Osaka (JP); Kazuki KOMAKI, Osaka (JP)

(21) Appl. No.: 17/939,669

(22) Filed: Sep. 7, 2022

Related U.S. Application Data
(63) Continuation of application No. PCT/JP2021/011940, filed on Mar. 23, 2021.

(30) Foreign Application Priority Data
Mar. 25, 2020 (JP) 2020-054663

(51) Int. Cl. G02B 26/08

(52) U.S. Cl. CPC G02B 26/0858

(57) ABSTRACT

An optical reflector element includes: a first oscillator and a second oscillator for oscillating a reflector and disposed with the reflector being interposed therebetween along a first axis; and a third oscillator for oscillating the first oscillator and the second oscillator. The third oscillator includes: a first assister that causes the support of the first oscillator and the support of the second oscillator to operate, by connecting the support of the first oscillator and the support of the second oscillator to one base included in a pair of bases disposed with the first axis being interposed therebetween; and a second assister that causes the support of the first oscillator and the support of the second oscillator to operate, by connecting the support of the first oscillator and the support of the second oscillator to an other base included in the pair of bases.

### CROSS REFERENCE TO RELATED APPLICATIONS

This is a continuation application of PCT International Application No, PCT/JP2021/011940 filed on Mar. 23, 2021, designating the United States of America, which is based on and claims priority of Japanese Patent Application No. 2020-054663 filed on Mar. 25, 2020. The entire disclosures of the above-identified applications, including the specifications, drawings and claims are incorporated herein by reference in theft entirety.

### FIELD

The present disclosure relates to an optical reflector element and a light control system that reciprocate an illumination position of a laser beam, for example.

### BACKGROUND

As disclosed in, for example, Patent Literature 1 (PTL 1), a conventional optical reflector element that reciprocates an illumination position of a laser beam includes: a reflector that reflects, for example, a laser beam; a connector that is connected to the reflector and is twisted to rotationally oscillate the reflector; two arm-shaped oscillation bodies that extend in a direction intersecting the rotation axis of the reflector to generate reciprocating twist in the connector; and drivers including, for example, piezoelectric elements that oscillate the oscillation bodies. With such an optical reflector element, the reflector rotates only in the twisting direction of the connector.

### CITATION LIST

### Patent Literature

PTL 1: Japanese Unexamined Patent Application Publication No. 2009-244602

### SUMMARY

### Technical Problem

The present disclosure has an object to enhance the performance of an optical reflector element.

### Solution to Problem

An optical reflector element according to an aspect of the present disclosure is an optical reflector element that reciprocates light by reflecting the light, the optical reflector element including: a reflector that reflects the light; a first oscillator and a second oscillator for oscillating the reflector and disposed with the reflector being interposed between the first oscillator and the second oscillator along a first axis; and a third oscillator for oscillating the first oscillator and the second oscillator, wherein each of the first oscillator and the second oscillator includes: a first connector disposed along the first axis and including a tip end portion and a base end portion, the tip end portion being coupled to the reflector; a first oscillation body that extends in a direction intersecting the first axis, includes a tip end portion, and is coupled to the base end portion of the first connector; a second oscillation body that extends in the direction intersecting the first axis, includes a tip end portion, and is coupled to the base end portion of the first connector, the second oscillation body being disposed on an opposite side of the first axis from the first oscillation body; a first driver that extends along the first axis, includes a base end portion coupled to the tip end portion of the first oscillation body, and causes the first connector to operate, via the first oscillation body; a second driver that extends along the first axis, includes a base end portion coupled to the tip end portion of the second oscillation body, and causes the first connector to operate, via the second oscillation body; a support extending in the direction intersecting the first axis; and a second connector that oscillatably connects the first oscillation body and the second oscillation body to the support, and the third oscillator includes: a first assister that causes the support of the first oscillator and the support of the second oscillator to operate, by connecting the support of the first oscillator and the support of the second oscillator to one base included in a pair of bases disposed with the first axis being interposed between the pair of bases; and a second assister that causes the support of the first oscillator and the support of the second oscillator to operate, by connecting the support of the first oscillator and the support of the second oscillator to an other base included in the pair of bases.

A light control system according to another aspect of the present disclosure is a light control system including: the optical reflector element described above; and a control device that controls the optical reflector element, wherein the control device oscillates the first driver and the second driver of the first oscillator, the first driver and the second driver of the second oscillator, and the first assister and the second assister of the third oscillator to rotationally oscillate the first oscillator and the second oscillator in a same direction around the first axis.

An optical reflector element according to an aspect of the present disclosure is an optical reflector element that reciprocates light by reflecting the light, the optical reflector element including: a reflector that reflects the light; a primary oscillator for oscillating the reflector and aligned with the reflector along a first axis; a first connector for transmitting oscillation of the primary oscillator to the reflector, the first connector being disposed along the first axis and including a base end portion; and a secondary oscillator for oscillating the primary oscillator, wherein the primary oscillator includes: a first oscillation body that extends in a direction intersecting the first axis, includes a tip end portion, and is coupled to the base end portion of the first connector; a second oscillation body that extends in the direction intersecting the first axis, includes a tip end portion, and is coupled to the base end portion of the first connector, the second oscillation body being disposed on an opposite side of the first axis from the first oscillation body; a first driver that extends along the first axis, includes a base end portion coupled to the tip end portion of the first oscillation body, and causes the first connector to operate, via the first oscillation body; a second driver that extends along the first axis, includes a base end portion coupled to the tip end portion of the second oscillation body, and causes the first connector to operate, via the second oscillation body; a support extending in the direction intersecting the first axis; and a second connector that oscillatably connects the first oscillation body and the second oscillation body to the support, and the secondary oscillator includes: a pair of bases; a first assister that causes the support of the primary oscillator to operate, by connecting the support of the primary oscillator to one base included in the pair of bases; and a second assister that causes the support of the primary oscillator to operate, by connecting the support of the primary oscillator to an other base included in the pair of bases.

A light control system according to another aspect of the present disclosure is a light control system including: the optical reflector element described above; and a control device that controls the optical reflector element, wherein the control device oscillates the first driver and the second driver of the primary oscillator and the first assister and the second assister of the secondary oscillator to rotationally oscillate the primary oscillator around the first axis.

### Advantageous Effects

According to the present disclosure, the performance of an optical reflector element can be enhanced.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a plan view illustrating an optical reflector element according to Embodiment 1.

FIG. 2 is a block diagram illustrating a control configuration of a light control system according to Embodiment 1.

FIG. 3 is an explanatory diagram illustrating an example of drive signals that cause the optical reflector element according to Embodiment 1 to operate.

FIG. 4 is a perspective view illustrating the state of each portion when the optical reflector element according to Embodiment 1 is in operation,

FIG. 5 is a graph schematically illustrating: oscillation in the case where a signal having a resonance frequency in a first mode is applied to the drivers according to Embodiment 1; and oscillation in the case where a signal having a resonance frequency in a second mode is applied to the drivers according to Embodiment 1.

FIG. 6 is a schematic diagram illustrating nodes that have occurred in an optical reflector element according to Embodiment 2.

FIG. 7 is a plan view illustrating an optical reflector element according to Embodiment 3.

FIG. 8 is a plan view illustrating an optical reflector element according to Embodiment 4.

FIG. 9 is a plan view illustrating a reflector according to Embodiment 5.

FIG. 10 is a plan view illustrating a variation of the reflector according to Embodiment 5.

### DESCRIPTION OF EMBODIMENTS

Next, embodiments of a light control system according to the present disclosure will be described with reference to the drawings. Note that each of the embodiments described below shows a general or specific example. The numerical values, shapes, materials, constituent elements, the arrangement and connection of the constituent elements, steps, the processing order of the steps etc. illustrated in the following embodiments are mere examples, and are not intended to limit the present disclosure. Among the constituent elements in the following embodiments, constituent elements not recited in any one of the independent claims representing the most generic concepts will be described as optional constituent elements.

The drawings are schematic diagrams in which emphasis, omissions, and proportion adjustments are made as appropriate to illustrate the present disclosure, and may differ from the actual shapes, positional relationships, and proportions.

In the following description and the drawings, the thickness direction of the optical reflector element is defined as the Z-axis direction. The direction parallel to the first axis of the optical reflector element is defined as the Y-axis direction, and the direction intersecting the first axis is defined as the X-axis direction. The X-axis direction, Y-axis direction, and Z-axis direction intersect each other (in the following embodiments, they are orthogonal to each other). Furthermore, expressions indicating a relative direction or posture, such as parallel and orthogonal, include cases where the direction or posture is not as stated in the strict sense. For example, an expression “two directions are orthogonal” means not only that the two directions are completely orthogonal, but also that they are substantially orthogonal, i.e., including a difference of several percentages, for example.

### Embodiment 1

### [Optical Reflector Element]

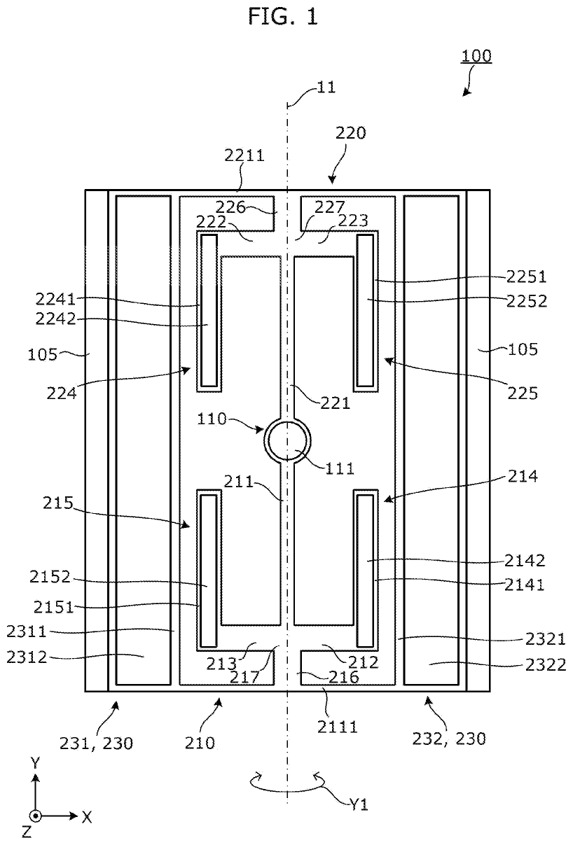

First, optical reflector element 100 according to the present disclosure will be described. FIG. 1 is a plan view illustrating optical reflector element 100 according to Embodiment 1.

Optical reflector element 100 is a device that periodically changes the angle of reflection of light such as a laser beam to periodically sweep the illumination position of the light. As illustrated in FIG. 1, optical reflector element 100 includes: a pair of bases 105; reflector 110; first oscillator 210 and second oscillator 220 that oscillate reflector 110; and third oscillator 230. In the present embodiment, part of reflector 110, part of first oscillator 210, part of second oscillator 220, part of third oscillator 230, and the pair of bases 105 are integrally formed by removing unnecessary portions from a single substrate. Specifically, for example, unnecessary portions of a silicon substrate are removed using an etching technique used in a semiconductor fabrication process, so as to integrally form part of reflector 110, part of first oscillator 210, part of second oscillator 220, part of third oscillator 230, and the pair of bases 105. Optical reflector element 100 is commonly known as micro-electro-mechanical systems (MEMS).

Here, a material included in the substrate may be, but is not particularly limited to, a material having a mechanical strength and a high Young's modulus, such as metal, crystalline body, glass, or resin, Specific examples include metal and an alloy such as silicon, titanium, stainless steel, elinvar, and a brass alloy. With use of such metal and alloy, for example, it is possible to implement optical reflector element 100 having excellent oscillation properties and processability.

Reflector 110 is a portion that reflects light by oscillation, Reflector 110 is in a circular plate shape in the present embodiment, but the shape is not particularly limited. Reflector 110 includes, on its surface, reflection component 111 capable of reflecting light that is targeted for reflection, at a high reflectance. A material of reflection component 111 can be freely selected. Examples of the material include metal such as gold, silver, copper, or aluminum, and metal compounds, Reflection component 111 may include plural layers. Further, reflection component 111 may be formed by smoothly polishing the surface of reflector 110. Reflection component 111 may have not only a flat surface but also a curved surface. First axis 11 is a central axis passing through the center of reflector 110.

First oscillator 210 and second oscillator 220 are disposed with reflector 110 being interposed therebetween along the first axis, Specifically, first oscillator 210 is disposed in the Y-axis negative direction with respect to reflector 110, and second oscillator 220 is disposed in the Y-axis positive direction with respect to reflector 110.

First oscillator 210 and second oscillator 220 have the same basic configuration, and are disposed to be symmetric with respect to the central point of optical reflector element 100. Thus, the specific configuration of first oscillator 210 will be described in detail, whereas the specific configuration of second oscillator 220 will be described simply.

First oscillator 210 includes first connector 211, first oscillation body 212, second oscillation body 213, first driver 214, second driver 215, second connector 216, and support 2111.

First connector 211 is a long rod-shaped portion extending along first axis 11. A tip end portion of first connector 211 is coupled to reflector 110, and a base end portion of first connector 211 is coupled to a base end portion of first oscillation body 212 and a base end portion of second oscillation body 213. First connector 211 is a portion for transmitting power to reflector 110 held at the tip end portion of first connector 211. Specifically, when first connector 211 is twisted around first axis 11, first connector 211 transmits rotational oscillation around first axis 11 to reflector 110.

The shape of first connector 211 is, but not particularly limited to, a thin rod shape with a width (a length in the X-axis direction in the figure) narrower than reflector 110, because first connector 211 is a component that is twisted to rotationally oscillate reflector 110. The expression “along first axis 11” includes not only the case where first connector 211 is straight along first axis 11 as in the present embodiment, but also the case where first connector 211 is curved meanderingly or bent in a zig-zag manner, so long as first connector 211 basically extends along first axis 11 that is virtually straight.

In the Specification and the Claims, the term “intersect” is used to include not only an intersection where two lines are in contact with one another, but also a three-dimensional intersection where two lines are not in contact with one another.

Oscillation bodies including first oscillation body 212 and second oscillation body 213 are arm-shaped portions that extend in the X-axis direction and oscillate to cause reflector 110 to operate. Specifically, first oscillation body 212 and second oscillation body 213 oscillate in the circumferential direction around first axis 11 to generate torque for rotationally oscillating reflector 110 around first axis 11.

First oscillation body 212 is disposed in a direction intersecting first axis 11 and is coupled to the base end portion of first connector 211. Second oscillation body 213 is disposed in the direction intersecting first axis 11 and is coupled to the base end portion of first connector 211, on the opposite side of first axis 11 from first oscillation body 212.

In the present embodiment, first oscillation body 212 is a rectangular rod-shaped component extending in the X-axis direction, and second oscillation body 213 is a rectangular rod-shaped component extending in a direction opposite to first oscillation body 212 in the X-axis direction.

The base end portion of first oscillation body 212 and the base end portion of second oscillation body 213 are integrally coupled by coupler 217, As a result, first oscillation body 212 and second oscillation body 213 form a shape of a straight rod extending in a direction orthogonal to first axis 11.

Drivers including first driver 214 and second driver 215 are components that generate a driving force to oscillate the oscillation bodies. First driver 214 is a component that is coupled to a tip end portion of first oscillation body 212 and oscillates first oscillation body 212. Second driver 215 is a component that is coupled to a tip end portion of second oscillation body 213 and oscillates second oscillation body 213.

First driver 214 includes first driver body 2141 and first piezoelectric element 2142. First driver body 2141 is a rod-shaped component that includes a base end portion integrally coupled to the tip end portion of first oscillation body 212, and extends toward reflector 110 along first axis 11. The entire length (the length in the Y-axis direction) of first driver body 2141 is longer than the entire length (length in the X-axis direction) of first oscillation body 212. First piezoelectric element 2142 is provided on the surface of first driver body 2141.

First piezoelectric element 2142 is an elongated plate-shaped piezoelectric element disposed on the surface of first driver body 2141 along first axis 11. First piezoelectric element 2142 is disposed at a position including a central portion of first driver 214, Specifically, first piezoelectric element 2142 is disposed over the entire length of first driver body 2141.

By applying a periodically-varying voltage to first piezoelectric element 2142, first piezoelectric element 2142 repeatedly expands and contracts. Corresponding to the movement of first piezoelectric element 2142, first driver body 2141 repeatedly bends and returns. First driver body 2141 oscillates more at the protruding tip end portion than at the base end portion coupled to first oscillation body 212, and the oscillation energy of first driver 214 as a whole is transmitted to the tip end of first oscillation body 212.

Similarly to first driver 214, second driver 215 includes second driver body 2151 and second piezoelectric element 2152, and is disposed at a position symmetric to the position of first driver 214 with respect to a virtual plane that includes first axis 11 and that is orthogonal to the surface of reflector 110. Second driver 215 includes a base end portion connected to the tip end of second oscillation body 213. The operation of second driver 215 is similar to that of first driver 214.

In the present embodiment, the piezoelectric elements are, for example, thin film laminated piezoelectric actuators, A thin film laminated piezoelectric actuator has a laminated structure which is formed on the surface of the driver body and in which at least one set of an electrode and a piezoelectric body is laminated in the thickness direction. This allows the driver to be thin.

Note that the drivers need not necessarily be of a type that oscillates as a result of distortion of the piezoelectric element. Other drivers include, for example: a driver that includes a component, a device, etc, which generates force through interaction with a magnetic field and an electric field, and that oscillates by changing at least one of a magnetic field or an electric field generated by an external device; and a driver that includes a component, a device, etc, which generates force through interaction with a magnetic field and an electric field, and that oscillates by changing at least one of a magnetic field or an electric field generated by the driver itself. Examples of a material used for the piezoelectric body include a piezoelectric material having a high piezoelectric constant, such as lead zirconate titanate (PZT).

Second connector 216 is a portion that oscillatably connects first oscillation body 212 and second oscillation body 213. Second connector 216 is disposed along first axis 11, and includes (i) a base end portion coupled to support 2111 and (ii) a tip end portion coupled to the base end portion of first oscillation body 212 and the base end portion of second oscillation body 213 via coupler 217.

The shape of second connector 216 is, but not particularly limited to, a shape of a rod that is more rigid in torsion than first connector 211, because second connector 216 is a component that is twisted as a result of the oscillations of first oscillation body 212 and second oscillation body 213 to allow first connector 211 to twist with respect to support 2111.

Note that, similarly to first connector 211, second connector 216 need not be straight along first axis 11, and may be curved meanderingly or may be bent in a zig-zag manner. Even in such cases, first connector 211 is less rigid in torsion around first axis 11 than second connector 216.

Support 2111 is a portion that is long in the X-axis direction, and includes a central portion coupled to the base end portion of second connector 216. One end portion and the other end portion of support 2111 are coupled to first assister 231 and second assister 232 of third oscillator 230, respectively.

Next, a specific structure of second oscillator 220 will be described. As described above, a basic configuration of second oscillator 220 is similar to that of first oscillator 210. Second oscillator 220 is disposed in such a manner that second oscillator 220 and first oscillator 210 are point-symmetric with respect to the central point of optical reflector element 100. Thus, the description will focus on the correspondence between the portions of second oscillator 220 and the portions of first oscillator 210.

Second oscillator 220 includes first connector 221, first oscillation body 222, second oscillation body 223, first driver 224, second driver 225, second connector 226, and support 2211.

First connector 221 is a portion corresponding to first connector 211 of first oscillator 210. First oscillation body 222 is a portion corresponding to first oscillation body 212 of first oscillator 210, and second oscillation body 223 is a portion corresponding to second oscillation body 213 of first oscillator 210. The positional relationship of first oscillation body 222 and second oscillation body 223 in the X-axis direction is opposite the positional relationship of first oscillation body 212 and second oscillation body 213 of first oscillator 210 in the X-axis direction. A base end portion of first oscillation body 222 and a base end portion of second oscillation body 223 are integrally coupled by coupler 227.

First driver 224 is a portion corresponding to first driver 214 of first oscillator 210, and second driver 225 is a portion corresponding to second driver 215 of first oscillator 210. The positional relationship of first driver 224 and second driver 225 in the X-axis direction is opposite the positional relationship of first driver 214 and second driver 215 of first oscillator 210 in the X-axis direction. First driver 224 includes first driver body 2241 and first piezoelectric element 2242, which correspond to first driver body 2141 and first piezoelectric element 2142 of first driver 214, respectively, Second driver 225 includes second driver body 2251 and second piezoelectric element 2252, which correspond to second driver body 2151 and second piezoelectric element 2152 of second driver 215, respectively.

Second connector 226 is a portion corresponding to second connector 216 of first oscillator 210. Second connector 226 is disposed along first axis 11, and includes (i) a base end portion coupled to support 2211 and (ii) a tip end portion coupled to the base end portion of first oscillation body 222 and the base end portion of second oscillation body 223 via coupler 227.

Support 2211 is a portion corresponding to support 2111 of first oscillator 210, Support 2211 is a portion that is long in the X-axis direction, and includes a central portion coupled to the base end portion of second connector 226. One end portion and the other end portion of support 2211 are coupled to first assister 231 and second assister 232 of third oscillator 230, respectively.

The pair of bases 105 are components for attaching optical reflector element 100 to, for example, an external structural component, and are in a rod shape which is long in the Y-axis direction. Specifically, the pair of bases 105 are disposed with first axis 11 being interposed therebetween, One of the paired bases 105 is coupled to first assister 231 of third oscillator 230, and the other of the paired bases 105 is coupled to second assister 232.

Next, a specific structure of third oscillator 230 will be described.

Third oscillator 230 is a portion that oscillates to exert an auxiliary force on first oscillator 210 and second oscillator 220 when first oscillator 210 and second oscillator 220 rotationally oscillate in the same direction around first axis 11. Third oscillator 230 includes first assister 231 and second assister 232.

First assister 231 is disposed in the X-axis negative direction with respect to first axis 11, and causes support 2111 of first oscillator 210 and support 2211 of second oscillator 220 to operate, by connecting support 2111 of first oscillator 210 and support 2211 of second oscillator 220 to one of the paired bases 105 which is disposed in the X-axis negative direction.

Specifically, first assister 231 includes first assister body 2311 and third piezoelectric element 2312. First assister body 2311 is a rectangular portion that is long in the Y-axis direction and extends continuously from one of the paired bases 105 to each of supports 2111 and 2211. In other words, an end portion of first assister body 2311 on the X-axis negative side is coupled to one of the paired bases 105 over the entire length in the Y-axis direction. An end portion of first assister body 2311 on the X-axis positive side includes corner portions. The corner portion on the Y-axis negative side is coupled to support 2111 of first oscillator 210, and the corner portion on the Y-axis positive side is coupled to support 2211 of second oscillator 220. First assister body 2311 is spaced apart from each of second driver 215 of first oscillator 210 and first driver 224 of second oscillator 220 in the X-axis direction.

Third piezoelectric element 2312 is an elongated plate-shaped piezoelectric element disposed on the surface of first assister body 2311 along first axis 11. Third piezoelectric element 2312 is disposed at a position including a central portion of first assister body 2311. Specifically, third piezoelectric element 2312 is disposed planarly over substantially the entire surface of first assister body 2311.

By applying a periodically-varying voltage to third piezoelectric element 2312, third piezoelectric element 2312 repeatedly expands and contracts. Corresponding to the movement of third piezoelectric element 2312, first assister body 2311 repeatedly bends and returns. The oscillation energy of first assister body 2311 as a whole is transmitted to support 2111 of first oscillator 210 and support 2211 of second oscillator 220. As a result, it is possible to oscillate support 2111 of first oscillator 210 and support 2211 of second oscillator 220.

Second assister 232 is disposed in the X-axis positive direction with respect to first axis 11, and causes support 2111 of first oscillator 210 and support 2211 of second oscillator 220 to operate, by connecting support 2111 of first oscillator 210 and support 2211 of second oscillator 220 to the other of the paired bases 105 which is disposed in the X-axis positive direction.

A basic configuration of second assister 232 is similar to that of first assister 231. Second assister 232 is disposed in such a manner that second assister 232 and first assister 231 are symmetric with respect to the virtual plane that includes first axis 11 and that is orthogonal to the surface of reflector 110. Thus, the description will focus on the correspondence between the portions of second assister 232 and the portions of first assister 231.

Second assister 232 includes second assister body 2321 and fourth piezoelectric element 2322. Second assister body 2321 is a portion corresponding to first assister body 2311, and fourth piezoelectric element 2322 is a portion corresponding to third piezoelectric element 2312.

Second assister body 2321 extends continuously from the other of the paired bases 105 to each of supports 2111 and 2211, By applying a periodically-varying voltage to fourth piezoelectric element 2322, fourth piezoelectric element 2322 repeatedly expands and contracts. Corresponding to the movement of fourth piezoelectric element 2322, second assister body 2321 repeatedly bends and returns. The oscillation energy of second assister body 2321 as a whole is transmitted to support 2111 of first oscillator 210 and support 2211 of second oscillator 220. As a result, it is possible to oscillate support 2111 of first oscillator 210 and support 2211 of second oscillator 220.

Note that the assisters need not necessarily be of a type that oscillates as a result of distortion of the piezoelectric element, Other assisters include, for example: an assister that includes a component, a device, etc. which generates force through interaction with a magnetic field and an electric field, and that oscillates by changing at least one of a magnetic field or an electric field generated by an external device; and an assister that includes a component, a device, etc. which generates force through interaction with a magnetic field and an electric field, and that oscillates by changing at least one of a magnetic field or an electric field generated by the assister itself,

### [Light Control System]

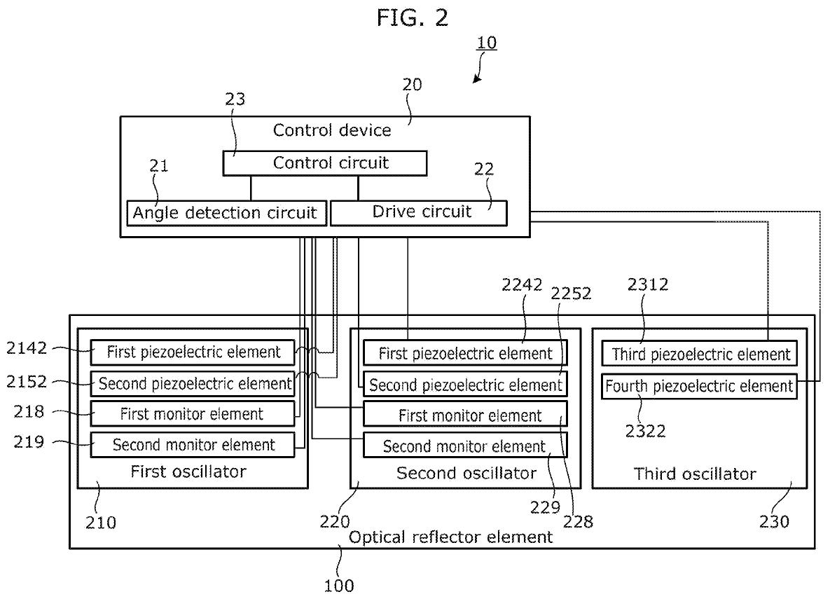

Next, light control system 10 including optical reflector element 100 described above will be described. FIG. 2 is a block diagram illustrating a control configuration of light control system 10 according to Embodiment 1.

As illustrated in FIG. 2, light control system 10 includes optical reflector element 100 and control device 20 that controls optical reflector element 100. Optical reflector element 100 includes a plurality of monitor elements attached at appropriate positions. The monitor elements are elements that detect a bending state of each oscillation body as distortion. By measuring the outputs of the monitor elements, it is possible to accurately monitor the oscillation state of reflector 110. Specifically, first oscillator 210 includes first monitor element 218 that detects distortion of first oscillation body 212 and second monitor element 219 that detects distortion of second oscillation body 213. Second oscillator 220 includes first monitor element 228 that detects distortion of first oscillation body 222 and second monitor element 229 that detects distortion of second oscillation body 223.

Control device 20 includes angle detection circuit 21, drive circuit 22, and control circuit 23. Angle detection circuit 21 is a circuit that receives a detection signal from each monitor element (first monitor elements 218 and 228 and second monitor elements 219 and 229), detects angle information of reflector 110 based on the detection signals, and outputs the angle information to control circuit 23.

Drive circuit 22 is a circuit that outputs a periodic voltage to each piezoelectric element (first piezoelectric elements 2142 and 2242, second piezoelectric elements 2152 and 2252, third piezoelectric element 2312, and fourth piezoelectric element 2322) based on a drive signal provided from control circuit 23.

Control circuit 23 is a circuit that adjusts the drive signal that control circuit 23 outputs to drive circuit 22 so that reflector 110 will be at a given angle, based on the angle information of reflector 110 received from angle detection circuit 21.

Note that the case described here is an example case where angle detection circuit 21, drive circuit 22, and control circuit 23 are dedicated circuits. Control device 20, however, may be executed by one or more electronic circuits including a semiconductor device, a semiconductor integrated circuit (IC), or a large-scale integrated circuit (LSI). The LSI or IC may be integrated on a single chip or may be formed by combining plural chips.

The monitor elements may be provided in reflector 110, but need not be provided in optical reflector element 100.

### [Operations]

Next, operations of optical reflector element 100 will be described. Optical reflector element 100 operates based on control performed by control device 20, Control device 20 rotationally oscillates reflector 110 around first axis 11. That is to say, control device 20 rotationally oscillates first oscillator 210 and second oscillator 220 in the same direction around first axis 11. At this time, control device 20 oscillates first driver 214 and second driver 215 of first oscillator 210 to cause each of first driver 214 and second driver 215 of first oscillator 210 to have a first portion and a second portion whose directions of oscillation in the thickness direction of optical reflector element 100 are opposite. Similarly, control device 20 oscillates first driver 224 and second driver 225 of second oscillator 220 to cause each of first driver 224 and second driver 225 of second oscillator 220 to have a third portion and a fourth portion whose directions of oscillation in the thickness direction are opposite.

Here, control device 20 oscillates first assister 231 and second assister 232 of third oscillator 230 to amplify the rotational oscillations of first oscillator 210 and second oscillator 220.

Hereinafter, a control method performed by control device 20 will be described.

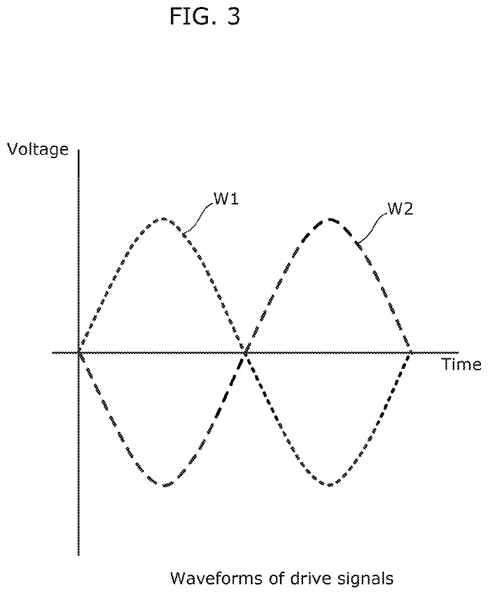

FIG. 3 is an explanatory diagram illustrating an example of drive signals that cause optical reflector element 100 according to Embodiment 1 to operate. The drive signals are signals for applying a periodically-varying AC voltage to each piezoelectric element, and have a resonant frequency which allows each driver to oscillate, FIG. 3 illustrates the waveform of first drive signal W1 and the waveform of second drive signal W2 of one period only, as an example of the drive signals. Second drive signal W2 has a waveform in a phase opposite to that of first drive signal W1. Control device 20 applies first drive signal W1 to first piezoelectric element 2142 of first oscillator 210 and second piezoelectric element 2252 of second oscillator 220, and applies second drive signal W2 to second piezoelectric element 2152 of first oscillator 210 and first piezoelectric element 2242 of second oscillator 220. This causes first oscillator 210 and second oscillator 220 to rotationally oscillate in the same direction around first axis 11.

At this time, control device 20 oscillates first assister 231 and second assister 232 of third oscillator 230 to amplify the rotational oscillations of first oscillator 210 and second oscillator 220. Specifically, control device 20 applies second drive signal W2 to third piezoelectric element 2312 of first assister 231, and applies first drive signal W1 to fourth piezoelectric element 2322. This causes first oscillator 210 and second oscillator 220 to oscillate, and their oscillations are transmitted to support 2111 of first oscillator 210 and support 2211 of second oscillator 220, thus amplifying the rotational oscillations of first oscillator 210 and second oscillator 220.

Here, with first oscillator 210 as an example, a specific example of first drive signal W1 and second drive signal W2 will be described. First drive signal W1 is set to a resonance frequency at which first driver 214 and second driver 215 of first oscillator 210 resonate in a mode of causing: first driver 214 to have first portion 214a and second portion 214b whose directions of oscillation in the thickness direction are opposite; and second driver 215 to have first portion 215a and second portion 215b whose directions of oscillation in the thickness direction are opposite. In other words, it can be said that first drive signal W1 is determined based on the natural frequency of first oscillator 210. Second drive signal W2 is set to substantially the same frequency as first drive signal W1, although second drive signal W2 is in a phase opposite to that of first drive signal W1. In the present embodiment, first drive signal W1 and second drive signal W2 have frequencies at which first driver 214 and second driver 215 of first oscillator 210 resonate in an eigenmode in which: first driver 214 has one inflection point between first portion 214a; and second portion 214b and second driver 215 has one inflection point between first portion 215a and second portion 215b. Note that first drive signal W1 and second drive signal W2 may have frequencies at which first driver 214 and second driver 215 of first oscillator 210 resonate in an eigenmode in which: first driver 214 has two or more inflection points between first portion 214a and second portion 214b; and second driver 215 has two or more inflection points between first portion 215a and second portion 215b.

As for second oscillator 220, first drive signal W1 corresponds to second driver 225 and second drive signal W2 corresponds to first driver 224,

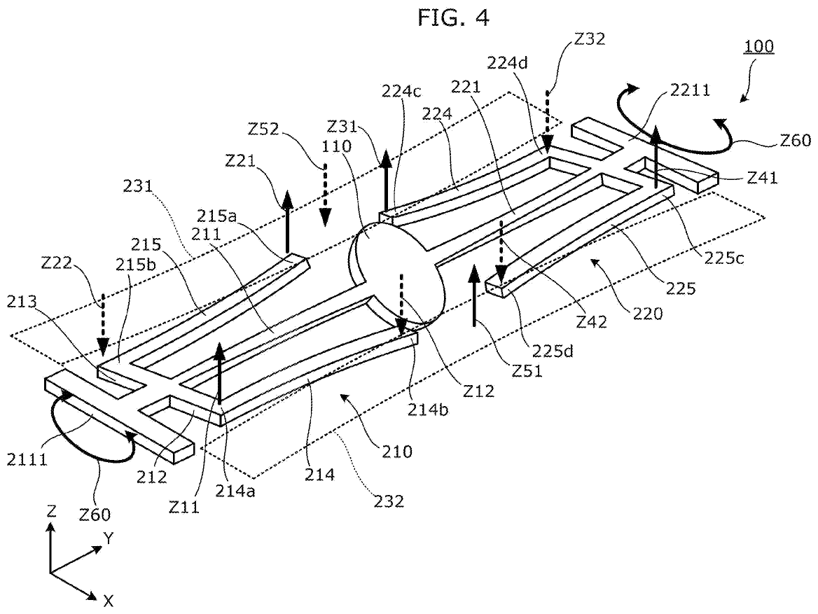

FIG. 4 is a perspective view illustrating the state of each portion when optical reflector element 100 according to Embodiment 1 is in operation. In FIG. 4, first assister 231 and second assister 232 of third oscillator 230 are shown with dashed lines.

As illustrated in FIG. 4, with first oscillator 210, application, by control device 20, of first drive signal W1 to first piezoelectric element 2142 and second drive signal W2 to second piezoelectric element 2152 causes: first driver 214 to have first portion 214a and second portion 214b whose directions of oscillation in the thickness direction are opposite; and second driver 215 to have first portion 215a and second portion 215b whose directions of oscillation in the thickness direction are opposite. Specifically, with first driver 214, first portion 214a is the base end portion of first driver 214 and second portion 214b is the tip end portion of first driver 214. When first portion 214a of first driver 214 moves in the Z-axis positive direction (arrow Z11 in FIG. 4), second portion 214b moves in the Z-axis negative direction (arrow Z12 in FIG. 4). Conversely, when first portion 214a of first driver 214 moves in the Z-axis negative direction, second portion 214b moves in the Z-axis positive direction.

With second driver 215, first portion 215a is the tip end portion of second driver 215 and second portion 215b is the base end portion of second driver 215. When first portion 215a of second driver 215 moves in the Z-axis positive direction (arrow Z21 in FIG. 4), second portion 215b moves in the Z-axis negative direction (arrow Z22 in FIG. 4). Conversely, when first portion 215a of second driver 215 moves in the Z-axis negative direction, second portion 215b moves in the Z-axis positive direction. This means that, first driver 214, first oscillation body 212, second driver 215, and second oscillation body 213 of first oscillator 210 rotationally oscillate in the same direction in the circumferential direction around first axis 11.

With second oscillator 220, application, by control device 20, of first drive signal W1 to second piezoelectric element 2252 and second drive signal W2 to first piezoelectric element 2242 causes: first driver 224 to have third portion 224c and fourth portion 224d whose directions of oscillation in the thickness direction are opposite; and second driver 225 to have third portion 225c and fourth portion 225d whose directions of oscillation in the thickness direction are opposite. Specifically, with first driver 224, third portion 224c is the tip end portion of first driver 224 and fourth portion 224d is the base end portion of first driver 224. When third portion 224c of first driver 224 moves in the Z-axis positive direction (arrow Z31 in FIG. 4), fourth portion 224d moves in the Z-axis negative direction (see arrow Z32 in FIG. 4). Conversely, when third portion 224c of first driver 224 moves in the Z-axis negative direction, fourth portion 224d moves in the Z-axis positive direction.

With second driver 225, third portion 225c is the base end portion of second driver 225 and fourth portion 225d is the tip end portion of second driver 225, When third portion 225c of second driver 225 moves in the Z-axis positive direction (arrow Z41 in FIG. 4), fourth portion 225d moves in the Z-axis negative direction (see arrow Z42 in FIG. 4). Conversely, when third portion 225c of second driver 225 moves in the Z-axis negative direction, fourth portion 225d moves in the Z-axis positive direction. This means that, similarly to first oscillator 210, first driver 224, first oscillation body 222, second driver 225, and second oscillation body 223 of second oscillator 220 rotationally oscillate in the same direction in the circumferential direction around first axis 11.

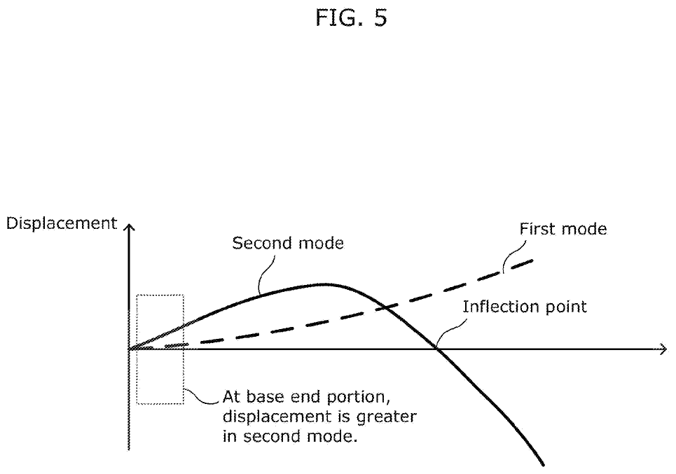

As described above, when first oscillator 210 and second oscillator 220 rotationally oscillate in the same direction around first axis 11, first connectors 211 and 221 are twisted around first axis 11, and thus reflector 110 also rotationally oscillates around first axis 11 (see arrow Y1 in FIG. 1), In the present embodiment, when first oscillator 210 and second oscillator 220 rotationally oscillate in the same direction around first axis 11, reflector 110 also rotationally oscillates around first axis 11 in the same direction as first oscillator 210 and second oscillator 220, FIG. 5 is a graph schematically illustrating: the oscillation in the case where a signal having a resonance frequency which does not cause an inflection point to occur is applied to the drivers (first drivers 214 and 224 and second drivers 215 and 225) according to Embodiment 1 (a first mode); and the oscillation in the case where a signal having a resonance frequency which causes an inflection point to occur is applied to the drivers (first drivers 214 and 224 and second drivers 215 and 225) according to Embodiment 1 (a second mode). The graph shows that the displacement of the base end portions of the drivers is greater in the second mode than in the first mode. Therefore, first oscillation bodies 212 and 222 and second oscillation bodies 213 and 223 rotationally oscillate significantly, thus twisting first connectors 211 and 221 significantly. As a result, the deflection angle of reflector 110 increases.

In third oscillator 230, when control device 20 applies second drive signal W2 to third piezoelectric element 2312 and applies first drive signal W1 to fourth piezoelectric element 2322, first assister 231 and second assister 232 oscillate in opposite directions in the thickness direction. Specifically, when first assister 231 moves in the Z-axis negative direction (arrow Z52 in FIG. 4), second assister 232 moves in the Z-axis positive direction (arrow Z51 in FIG. 4).

Conversely, when first assister 231 moves in the Z-axis positive direction, second assister 232 moves in the Z-axis negative direction. As this oscillation is repeated, support 2111 of first oscillator 210 and support 2211 of second oscillator 220 rotationally oscillate in the circumferential direction around first axis 11 (see arrow Z60 in FIG. 4). The direction of the rotational oscillations of supports 2111 and 2211 is the same as the direction of the rotational oscillations of first oscillator 210 and second oscillator 220. Therefore, when the rotational oscillations of supports 2111 and 2211 are transmitted to first oscillator 210 and second oscillator 220, the rotational oscillations of first oscillator 210 and second oscillator 220 are amplified. That is to say, the rotational oscillation of reflector 110 is also amplified.

### [Advantageous Effects etc.]

As described above, according to the present embodiment, optical reflector element 100 that reciprocates light by reflecting the light includes: reflector 110 that reflects the light; first oscillator 210 and second oscillator 220 for oscillating reflector 110 and disposed with reflector 110 being interposed between first oscillator 210 and second oscillator 220 along first axis 11; and third oscillator 230 for oscillating first oscillator 210 and second oscillator 220. Each of first oscillator 210 and second oscillator 220 includes: first connector 211, 221 disposed along first axis 11 and including a tip end portion and a base end portion, the tip end portion being coupled to reflector 110; first oscillation body 212, 222 that extends in a direction intersecting first axis 11, includes a tip end portion, and is coupled to the base end portion of first connector 211, 221; second oscillation body 213, 223 that extends in the direction intersecting first axis 11, includes a tip end portion, and is coupled to the base end portion of first connector 211, 221, second oscillation body 213, 223 being disposed on an opposite side of first axis 11 from first oscillation body 212, 222; first driver 214, 224 that extends along first axis 11, includes a base end portion coupled to the tip end portion of first oscillation body 212, 222, and causes first connector 211, 221 to operate, via first oscillation body 212, 222; second driver 215, 225 that extends along first axis 11, includes a base end portion coupled to the tip end portion of second oscillation body 213, 223, and causes first connector 211, 221 to operate, via second oscillation body 213, 223; support 2211, 2211 extending in the direction intersecting first axis 11; and second connector 216, 226 that oscillatably connects first oscillation body 212, 222 and second oscillation body 213, 223 to support 2211, 2211. Third oscillator 230 includes: first assister 231 that causes support 2111 of first oscillator 210 and support 2211 of the second oscillator to operate, by connecting support 2111 of first oscillator 210 and support 2211 of second oscillator 220 to one base 105 included in a pair of bases 105 disposed with first axis 11 being interposed between the pair of bases 105; and second assister 232 that causes support 2111 of first oscillator 210 and support 2211 of second oscillator 220 to operate, by connecting support 2111 of first oscillator 210 and support 2211 of second oscillator 220 to other base 105 included in the pair of bases 105.

According to the present embodiment, light control system 10 includes optical reflector element 100 described above and control device 20 that controls optical reflector element 100, Control device 20 oscillates first driver 214 and second driver 215 of first oscillator 210, first driver 224 and second driver 225 of second oscillator 220, and first assister 231 and second assister 232 of third oscillator 230 to rotationally oscillate first oscillator 210 and second oscillator 220 in a same direction around first axis 11.

According to this, first assister 231 of third oscillator 230 is connected to support 2111 of first oscillator 210 and support 2211 of second oscillator 220, and second assister 232 is connected to support 2111 of first oscillator 210 and support 2211 of second oscillator 220. Therefore, when control device 20 oscillates first assister 231 and second assister 232 in opposite directions in the thickness direction, their oscillations are transmitted to first oscillator 210 and second oscillator 220 via supports 2111 and 2211, That is to say, the rotational oscillations of first oscillator 210 and second oscillator 220 can be amplified. As a result, first connectors 211 and 221 are twisted significantly, and the deflection angle of reflector 110 can be increased, Therefore, the oscillation range of reflector 110 can be expanded, and the performance of optical reflector element 100 can be enhanced.

First drivers 214 and 224 include first piezoelectric elements 2142 and 2242, respectively, and second drivers 215 and 225 include second piezoelectric element 2152 and 2252, respectively. First assister 231 includes: first assister body 2311 extending continuously from one base 105 to support 2111 of first oscillator 210 and support 2211 of second oscillator 220; and third piezoelectric element 2312 stacked on substantially an entire surface of first assister body 2311. Second assister 232 includes: second assister body 2321 extending continuously from other base 105 to support 2111 of first oscillator 210 and support 2211 of second oscillator 220; and fourth piezoelectric element 2322 stacked on substantially an entire surface of second assister body 2322.

According to this, since third piezoelectric element 2312 is stacked on substantially the entire surface of first assister body 2311 and fourth piezoelectric element 2322 is stacked on substantially the entire surface of second assister body 2321, each of third piezoelectric element 2312 and fourth piezoelectric element 2322 can be stacked over a wide area. This allows the volume of third piezoelectric element 2312 and fourth piezoelectric element 2322 to be relatively large. The larger the volumes of third piezoelectric element 2312 and fourth piezoelectric element 2322 are, the larger the oscillations it is possible to generate, and as a result, the rotational oscillations of first oscillator 210 and second oscillator 220 can be further amplified. Therefore, the oscillation range of reflector 110 can be expanded, and the performance of optical reflector element 100 can be further enhanced.

The entire lengths of first drivers 214 and 224 are longer than the entire lengths of first oscillation bodies 212 and 222, respectively, and the entire lengths of second drivers 215 and 225 are longer than the entire lengths of second oscillation bodies 213 and 223, respectively.

According to this, for example, since the entire length of first driver 214 is longer than the entire length of first oscillation body 212, the rotational torque with respect to the base end portion of first driver 214 can be increased. The same applies to the other drivers (first driver 224 and second drivers 215 and 225). Accordingly, since the rotational torque with respect to the base end portion of each driver is increased, the drive efficiency can be enhanced.

Note that the ratio between the entire length of the driver (first drivers 214 and 224 and second drivers 215 and 225) and the entire length of the oscillation body (first oscillation bodies 212 and 222 and second oscillation bodies 213 and 223) is preferably at least 0.15 and at most 0.5, With this relationship, it is possible to suitably increase the rotational torque with respect to the base end portion of the driver. In each driver whose entire length is longer than that of the oscillation body, the piezoelectric element (first piezoelectric elements 2142 and 2242 and second piezoelectric elements 2152 and 2252) is provided over the entire length of the driver. This allows the volume of the piezoelectric element to be relatively large. The larger the volume of the piezoelectric element is, the larger the oscillation it is possible to generate in the driver, and thus the driving efficiency can be increased.

### Embodiment 2

Next, Embodiment 2 will be described. Note that in the following description, the components and the portions identical to those in Embodiment 1 above are given identical reference signs, and the descriptions thereof may be omitted.

In Embodiment 1, a description has been given of the example case where when first oscillator 210 and second oscillator 220 rotationally oscillate in the same direction around first axis 11, reflector 110 also rotationally oscillates in the same direction around first axis 11. In Embodiment 2, a description will be given of a case where when first oscillator 210 and second oscillator 220 rotationally oscillate in the same direction around first axis 11, reflector 110 rotationally oscillates in the direction opposite to first oscillator 210 and second oscillator 220. In Embodiment 2, a method of controlling, for example, optical reflector element 100 according to Embodiment 1 will also be described.

Specifically, each of first connectors 211 and 221 is in a shape in which an odd number of nodes occur when, for example, first drive signal W1 and second drive signal W2 are applied to first drivers 214 and 224 and second drivers 215 and 225. For example, by adjusting the entire length, cross-sectional shape, external shape, etc. of each of first connectors 211 and 221, each of first connectors 211 and 221 is in such a shape in which an odd number of nodes occur.

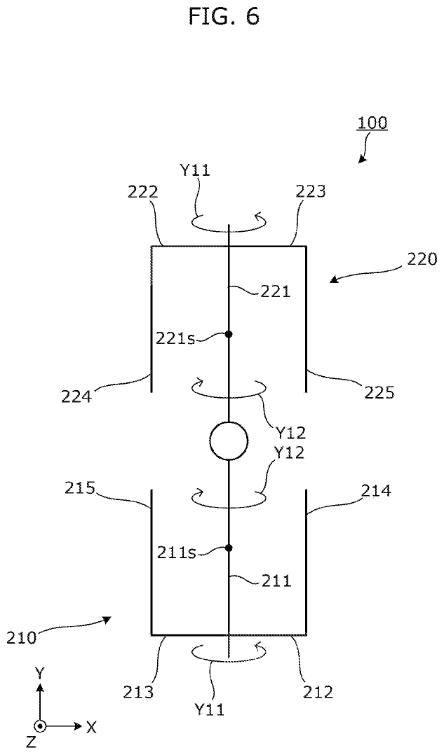

FIG. 6 is a schematic diagram illustrating nodes that have occurred in optical reflector element 100 according to Embodiment 2, In FIG. 6, third oscillator 230 is not shown. As illustrated in FIG. 6, one node 211s has occurred at the middle position of first connector 211, and one node 221s has occurred at the middle position of first connector 221. Here, a “node” refers to a portion where, in its vicinity, the direction of twist of first connector 211, 221 is reversed.

When counterclockwise rotations around first axis 11 (arrows Y11 in FIG. 6) are generated at the base end portions of first connectors 211 and 221 by the control performed by control device 20, clockwise rotations around first axis 11 (arrows Y12 in FIG. 6) are generated at the tip end portions located away from nodes 211s and 221s. This causes reflector 110 to rotate clockwise, too.

Conversely, when clockwise rotations around first axis 11 are generated at the base end portions of first connectors 211 and 221, counterclockwise rotations around first axis 11 are generated at the tip end portions located away from nodes 211s and 221s, This causes reflector 110 to rotate counterclockwise, too.

That is to say, as a result of these operations being repeated, first oscillator 210 and second oscillator 220 rotationally oscillate in the same direction around first axis 11, which causes reflector 110 to rotationally oscillate in the direction opposite to first oscillator 210 and second oscillator 220.

### [Advantageous Effects Etc.]

As described above, according to the present embodiment, first connector 211 of first oscillator 210 and first connector 221 of second oscillator 220 are each in a shape in which an odd number of nodes 211s, 221s occur when first oscillator 210 and second oscillator 220 are rotationally oscillated in the same direction.

According to this, when first oscillator 210 and second oscillator 220 rotationally oscillate in the same direction around first axis 11, reflector 110 rotationally oscillates in the direction opposite to first oscillator 210 and second oscillator 220. At this time, since the direction of twist of first connectors 211 and 221 is reversed at nodes 211s and 221s, an oscillation confining effect is produced. This leads to an increase in the resonance sharpness (Q factor) in a resonance mode for rotating reflector 110, i.e., a resonance mode (drive mode) that optical reflector element 100 has. An increase in the resonance sharpness (Q factor) can lead to enhancement in the deflection angle characteristics of reflector 110. In other words, in Embodiment 2, it is possible to rotationally oscillate reflector 110 in a range greater than that of reflector 110 according to Embodiment 1.

Note that the case described in the present embodiment is the example case where one node 211s occurs in first connector 211 and one node 221s occurs in first connector 221, but a total number of nodes that occur in one connector may be an odd number greater than or equal to 3. As long as a total number of nodes that occur is an odd number, the rotational oscillations of first oscillator 210 and second oscillator 220 in the same direction around first axis 11 cause reflector 110 to rotationally oscillate in the direction opposite to first oscillator 210 and second oscillator 220.

When control device 20 is to oscillate first oscillator 210 and second oscillator 220 in the same direction, control device 20: oscillates first driver 214 and second driver 215 of first oscillator 210 to cause (i) first driver 214 of first oscillator 210 to have first portion 214a and second portion 214b whose directions of oscillation in the thickness direction are opposite, and (ii) second driver 215 of first oscillator 210 to have first portion 215a and second portion 215b whose directions of oscillation in the thickness direction are opposite; and oscillates first driver 224 and second driver 225 of second oscillator 220 to cause (iii) first driver 224 of second oscillator 220 to have third portion 224c and fourth portion 224d whose directions of oscillation in the thickness direction are opposite, and (iv) second driver 225 of second oscillator 220 to have third portion 225c and fourth portion 225d whose directions of oscillation in the thickness direction are opposite.

This causes first driver 214 of first oscillator 210 to have first portion 214a and second portion 214b whose directions of oscillation in the thickness direction are opposite, and causes second driver 215 of first oscillator 210 to have first portion 215a and second portion 215b whose directions of oscillation in the thickness direction are opposite. As a result, it is possible to increase displacement of first driver 214 and second driver 215 at the base end portions thereof.

This also causes first driver 224 of second oscillator 220 to have third portion 224c and fourth portion 224d whose directions of oscillation in the thickness direction are opposite, and causes second driver 225 of second oscillator 220 to have third portion 225c and fourth portion 225d whose directions of oscillation in the thickness direction are opposite. As a result, it is possible to increase displacement of first driver 224 and second driver 225 at the base end portions thereof.

With these, first oscillation bodies 212 and 222 and second oscillation bodies 213 and 223 also rotationally oscillate significantly, and thus first connectors 211 and 221 are also twisted significantly, and the deflection angle of reflector 110 can be further increased. Therefore, the oscillation range of reflector 110 can be expanded, and the performance of optical reflector element 100 can be further enhanced.

### Embodiment 3

Next, Embodiment 3 will be described. Note that in the following description, the components and the portions identical to those in Embodiment 1 above are given identical reference signs, and the descriptions thereof may be omitted.

The case described in the above embodiments is the example case where first assister 231 and second assister 232 of third oscillator 230 are continuous from support 2111 of first oscillator 210 to support 2211 of second oscillator 220. Each of the first assister and the second assister, however, may be divided.

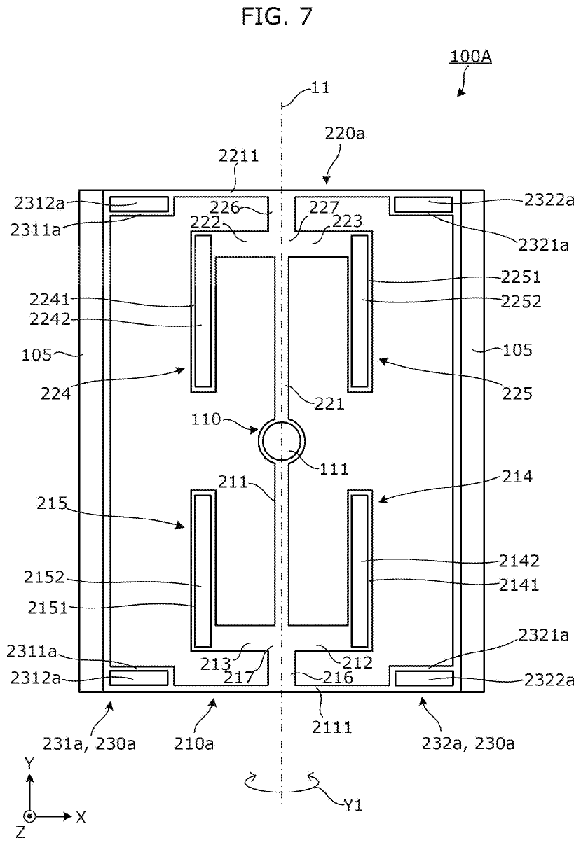

FIG. 7 is a plan view illustrating optical reflector element 100A according to Embodiment 3. As illustrated in FIG. 7, with optical reflector element 100A according to Embodiment 3, each of first assister 231a and second assister 232a of third oscillator 230a is divided in the Y-axis direction.

Specifically, first assister 231a includes a pair of first assister bodies 2311a and a pair of third piezoelectric elements 2312a, The paired first assister bodies 2311a are spaced apart in the Y-axis direction. One first assister 2311a of the paired first assister bodies 2311a is long in the X-axis direction and couples support 2111 of first oscillator 210 and one of bases 105. One third piezoelectric element 2312a of the paired third piezoelectric elements 2312a is stacked on the surface of the one first assister body 2311a.

The other first assister body 2311a of the paired first assister bodies 2311a is long in the X-axis direction, and couples support 2211 of second oscillator 220 and the one of bases 105. The other third piezoelectric element 2312a of the paired third piezoelectric elements 2312a is stacked on the surface of the other first assister body 2311a.

Second assister 232a includes a pair of second assister bodies 2321a and a pair of fourth piezoelectric elements 2322a, Second assister 232a is basically the same as first assister 231a, so the details thereof are omitted.

In this case, when first oscillator 210 and second oscillator 220 rotationally oscillate in the same direction around first axis 11, control device 20 applies first drive signal W1 to the pair of fourth piezoelectric elements 2322a and applies second drive signal W2 to the pair of third piezoelectric elements 2312a, so that the rotational oscillations of first oscillator 210 and second oscillator 220 can be amplified.

Note that the case described in the present embodiment is the example case where first assister 231a and second assister 232a are each divided in the Y-axis direction; however, first assister 231a and second assister 232a may be divided in the X-axis direction.

### Embodiment 4

Next, Embodiment 4 will be described. Note that in the following description, the components and the portions identical to those in Embodiment 1 above are given identical reference signs, and the descriptions thereof may be omitted.

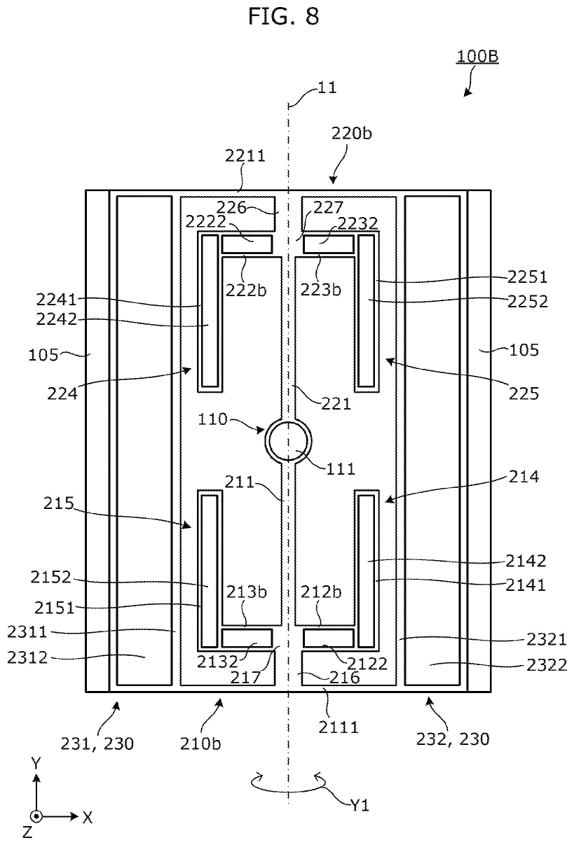

In Embodiment 4, optical reflector element 100B in which the first oscillation bodies and the second oscillation bodies include piezoelectric elements will be described as an example. FIG. 8 is a plan view illustrating optical reflector element 100B according to Embodiment 4. Specifically, FIG. 8 corresponds to FIG. 1. Note that the description of the assisters is omitted here.

As illustrated in FIG. 8, in first oscillator 210b of optical reflector element 100B, first oscillation body 212b includes fifth piezoelectric element 2122, and second oscillation body 213b includes sixth piezoelectric element 2132. Specifically, fifth piezoelectric element 2122 is disposed on the surface of first oscillation body 212b. Fifth piezoelectric element 2122 is disposed at a position including a central portion of first oscillation body 212b. In the present embodiment, fifth piezoelectric element 2122 is disposed over the entire length of first oscillation body 212b. As described earlier, first piezoelectric element 2142 is disposed over the entire length of first driver 214, Therefore, the inflection point that occurs in the entirety of first driver 214 and first oscillation body 212b when first driver 214 and first oscillation body 212b oscillate is included in first piezoelectric element 2142. In other words, the entirety of fifth piezoelectric element 2122 and at least a portion of first piezoelectric element 2142 are included in a region between the base point of first oscillation body 212b and the inflection point, Sixth piezoelectric element 2132 is disposed on the surface of second oscillation body 213b, Sixth piezoelectric element 2132 is disposed at a position including a central portion of second oscillation body 213b. In the present embodiment, sixth piezoelectric element 2132 is disposed over the entire length of second oscillation body 213b. As described earlier, second piezoelectric element 2152 is disposed over the entire length of second driver 215, Therefore, the inflection point that occurs in the entirety of second driver 215 and second oscillation body 213b when second driver 215 and second oscillation body 213b oscillate is included in second piezoelectric element 2152. In other words, the entirety of sixth piezoelectric element 2132 and at least a portion of second piezoelectric element 2152 are included in a region between the base point of second oscillation body 213b and the inflection point.

Note that also with second oscillator 220b, first oscillation body 222b includes fifth piezoelectric element 2222 and second oscillation body 223b includes sixth piezoelectric element 2232, but the descriptions thereof are omitted since they are basically the same as those in first oscillator 210b.

Each of fifth piezoelectric elements 2122 and 2222 and sixth piezoelectric elements 2132 and 2232 is electrically connected to control device 20. When control device 20 is to rotationally oscillate first oscillator 210b and second oscillator 220b to cause first oscillator 210b and second oscillator 220b to rotate in the same direction around first axis 11, control device 20 oscillates fifth piezoelectric elements 2122 and 2222 and sixth piezoelectric elements 2132 and 2232.

Specifically, control device 20 applies first drive signal W1 to first piezoelectric element 2142 and sixth piezoelectric element 2132 of first oscillator 210b and second piezoelectric element 2252 and fifth piezoelectric element 2222 of second oscillator 220b, and applies second drive signal W2 to second piezoelectric element 2152 and fifth piezoelectric element 2122 of first oscillator 210b and first piezoelectric element 2242 and sixth piezoelectric element 2232 of second oscillator 220b.

As a result, with first oscillator 210b, first oscillation body 212b oscillates in the direction opposite to first driver 214 in the thickness direction, and second oscillation body 213b oscillates in the direction opposite to second driver 215 in the thickness direction. With second oscillator 220b, first oscillation body 222a oscillates in the direction opposite to first driver 224 in the thickness direction, and second oscillation body 223b oscillates in the direction opposite to second driver 225 in the thickness direction. As a result, for example, first driver 214 is excited by the stimulation by the oscillation of first oscillation body 212b, and therefore oscillates more significantly. The same applies to each driver, and thus, each of first oscillator 210b and second oscillator 220b rotationally oscillates significantly.

### [Advantageous Effects etc.]

As described above, according to the present embodiment, control device 20: oscillates second oscillation body 213b of first oscillator 210b in a direction opposite to second driver 215 in the thickness direction, while oscillating first oscillation body 212b of first oscillator 210b in a direction opposite to first driver 214 in the thickness direction; and oscillates second oscillation body 223b of second oscillator 220b in a direction opposite to second driver 225 in the thickness direction, while oscillating first oscillation body 222b of second oscillator 220b in a direction opposite to first driver 224 in the thickness direction.

According to this, the oscillation of each oscillation body excites a driver, and thus the oscillation of each driver can be amplified. As a result, each of first oscillator 210b and second oscillator 220b rotationally oscillates significantly, and the driving efficiency can be increased.

First oscillation bodies 212b and 222b include fifth piezoelectric elements 2122 and 2222, respectively. Second oscillation bodies 213b and 223b include sixth piezoelectric elements 2132 and 2232, respectively, First piezoelectric element 2142 is disposed at a position including the inflection point that occurs in the entirety of first driver 214 and first oscillation body 212b during oscillation, and first piezoelectric element 2242 is disposed at a position including the inflection point that occurs in the entirety of first driver 224 and first oscillation body 222b during oscillation, Second piezoelectric element 2152 is disposed at a position including the inflection point that occurs in the entirety of second driver 215 and second oscillation body 213b during oscillation, and second piezoelectric element 2252 is disposed at a position including the inflection point that occurs in the entirety of second driver 225 and second oscillation body 223b during oscillation.

According to this, in the entirety of first driver 214 and first oscillation body 212b, the entirety of fifth piezoelectric element 2122 and at least a portion of first piezoelectric element 2142 are included in a region between the base point of first oscillation body 212b and the inflection point, and in the entirety of first driver 224 and first oscillation body 222b, the entirety of fifth piezoelectric element 2222 and at least a portion of first piezoelectric element 2242 are included in a region between the base point of first oscillation body 222b and the inflection point. This means that a plurality of piezoelectric elements are included in each of the region between the base point of first oscillation body 212b and the inflection point and the region between the base point of first oscillation body 222b and the inflection point, and thus, first drivers 214 and 224 and first oscillation bodies 212b and 222b can be easily excited.

Similarly, in the entirety of second driver 215 and second oscillation body 213b, the entirety of sixth piezoelectric element 2132 and at least a portion of second piezoelectric element 2152 are included in a region between the base point of second oscillation body 213b and the inflection point, and in the entirety of second driver 225 and second oscillation body 223b, the entirety of sixth piezoelectric element 2232 and at least a portion of second piezoelectric element 2252 are included in a region between the base point of second oscillation body 223b and the inflection point. This means that a plurality of piezoelectric elements are included in each of the region between the base point of second oscillation body 213b and the inflection point and the region between the base point of second oscillation body 223b and the inflection point, and thus, second drivers 215 and 225 and second oscillation bodies 213b and 223b can be easily excited.

### Embodiment 5

Next, Embodiment 5 will be described. Note that in the following description, the components and the portions identical to those in Embodiment 1 above are given identical reference signs, and the descriptions thereof may be omitted.

In Embodiment 1 above, reflector 110 which is in a circular plate shape has been described as an example, but in Embodiment 5, reflector 110b that yields a stress mitigation effect higher than that of reflector 110 in a circular plate shape will be described.

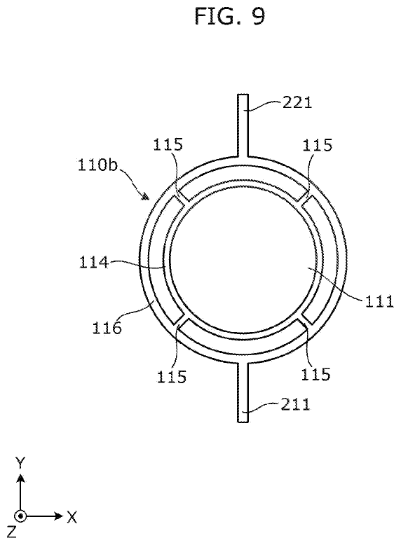

FIG. 9 is a plan view illustrating reflector 110b according to Embodiment 5. As illustrated in FIG. 9, reflector 110b includes reflector body 114, pillars 115, and frame 116, Reflector body 114 is in a circular plate shape, and reflection component 111 is provided on the surface of reflector body 114. Pillars 115 are disposed at predetermined intervals in the circumferential direction from the peripheral edge of reflector body 114. Each pillar 115 protrudes outwardly from the outer peripheral surface of reflector body 114. Frame 116 is in a ring shape and disposed in such a manner that frame 116 and reflector body 114 are arranged concentrically. Frame 116 is coupled to tip end portions of pillars 115. The tip end portion of first connector 211 of first oscillator 210 and the tip end portion of first connector 221 of second oscillator 220 are connected to the outer peripheral surface of frame 116. Thus, the twists and oscillations of first connectors 211 and 221 are transmitted to reflector body 114 via frame 116 and pillars 115. In other words, since the twists and oscillations of first connectors 211 and 221 are not directly transmitted to reflector body 114, the stress applied to reflector body 114 is mitigated.

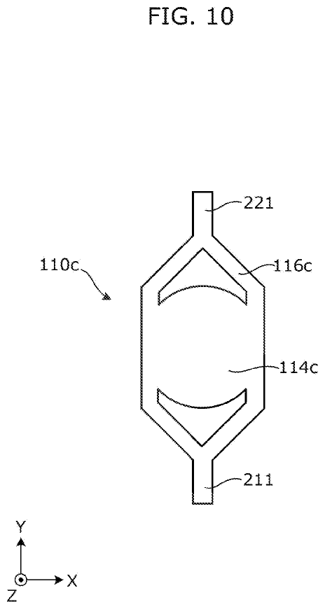

The shape of the reflector may be any shape as long as the stress mitigation effect can be achieved. FIG. 10 is a plan view illustrating reflector 110c, which is a variation of Embodiment 5. As illustrated in FIG. 10, reflector 110c does not include pillars, and frame 116c is in substantially a hexagonal loop shape. Frame 116c includes a pair of corner portions which face each other in the Y-axis direction and to which the tip end portion of first connector 211 of first oscillator 210 and the tip end portion of first connector 221 of second oscillator 220 are joined. Frame 116c also includes a pair of sides which face each other in the X-axis direction and to which reflector body 114c is joined inside frame 116c, The stress mitigation effect can be achieved also by such reflector 110c having gaps between parts of frame 116c and reflector body 114c,

### [Other]

Note that the present disclosure is not limited to the above embodiments. For example, the present disclosure also encompasses other embodiments implemented by arbitrarily combining the constituent elements described in the Specification or by excluding some of the constituent elements. The present disclosure also encompasses variations achieved by making various modifications conceivable to a person skilled in the art to the above embodiments without departing from the essence of the present disclosure, i.e., the meaning indicated by the wording used in the Claims.

For example, according to Embodiment 1 above, first driver 214 of first oscillator 210 has first portion 214a and second portion 214b whose directions of oscillation in the thickness direction are opposite, and second driver 215 of first oscillator 210 has first portion 215a and second portion 215b whose directions of oscillation in the thickness direction are opposite. That is to say, a description has been given of the example case where, for example, first driver 214 has two portions (first portion 214a and second portion 214b) that oscillate in opposite directions, and second driver 215 has two portions (first portion 215a and second portion 215b) that oscillate in opposite directions. However, one driver may be provided with three or more portions that oscillate in opposite directions. The same applies to each of first driver 224 and second driver 225 of second oscillator 220.

In Embodiment 1 above, light control system 10 that includes two oscillators, namely first oscillator 210 and second oscillator 220, has been described as an example. The light control system, however, may include only one oscillator.

That is to say, an optical reflector element includes: a reflector that reflects light; a primary oscillator for oscillating the reflector and aligned with the reflector along a first axis; a first connector for transmitting oscillation of the primary oscillator to the reflector, the first connector being disposed along the first axis and including a base end portion; and a secondary oscillator for oscillating the primary oscillator. The primary oscillator includes: a first oscillation body that extends in a direction intersecting the first axis, includes a tip end portion, and is coupled to the base end portion of the first connector; a second oscillation body that extends in the direction intersecting the first axis, includes a tip end portion, and is coupled to the base end portion of the first connector, the second oscillation body being disposed on an opposite side of the first axis from the first oscillation body; a first driver that extends along the first axis, includes a base end portion coupled to the tip end portion of the first oscillation body, and causes the first connector to operate, via the first oscillation body; a second driver that extends along the first axis, includes a base end portion coupled to the tip end portion of the second oscillation body, and causes the first connector to operate, via the second oscillation body; and a second connector that oscillatably connects the first oscillation body and the second oscillation body to a support of the secondary oscillator. The secondary oscillator may include: the support extending in the direction intersecting the first axis; a pair of bases; a first assister that causes the support to operate, by connecting the support to one base included in the pair of bases; and a second assister that causes the support to operate, by connecting the support to an other base included in the pair of bases.

At this time, the control device of the light control system oscillates the first driver and the second driver of the primary oscillator and the first assister and the second assister of the secondary oscillator to rotationally oscillate the primary oscillator around the first axis.

For example, in the case where second oscillator 220 is excluded from Embodiment 1, the primary oscillator corresponds to first oscillator 210 and the secondary oscillator corresponds to the pair of bases 105 and third oscillator 230. Note that, in this case, the oscillations of the primary oscillator and the secondary oscillator can be effectively amplified by having support 2111 as a portion of the secondary oscillator.

Even in this case, the rotational oscillation of the primary oscillator can be amplified by the rotational oscillation of the secondary oscillator. As a result, the first connector is twisted significantly, and the deflection angle of the reflector can be increased. Therefore, the oscillation range of the reflector can be expanded, and the performance of the optical reflector element can be enhanced.

In this case, it is preferable if the resonance frequency of the primary oscillator and the resonance frequency of the secondary oscillator are identical, because a stable amplification effect can be achieved. In particular, it is further preferable if the resonance frequency of a structure body coupling the primary oscillator and the secondary oscillator and the resonance frequency of a structure body coupling the reflector and the first connector are identical.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The present disclosure is applicable to, for example, optical devices such as small display devices, small projectors, in-vehicle head-up display devices, electrophotographic copiers, laser printers, optical scanners, and optical radars.

1. An optical reflector element that reciprocates light by reflecting the light, the optical reflector element comprising:
a reflector that reflects the light;
a first oscillator and a second oscillator for oscillating the reflector and disposed with the reflector being interposed between the first oscillator and the second oscillator along a first axis; and
a third oscillator for oscillating the first oscillator and the second oscillator,
wherein each of the first oscillator and the second oscillator includes:
a first connector disposed along the first axis and including a tip end portion and a base end portion, the tip end portion being coupled to the reflector;
a first oscillation body that extends in a direction intersecting the first axis, includes a tip end portion, and is coupled to the base end portion of the first connector;
a second oscillation body that extends in the direction intersecting the first axis, includes a tip end portion, and is coupled to the base end portion of the first connector, the second oscillation body being disposed on an opposite side of the first axis from the first oscillation body;
a first driver that extends along the first axis, includes a base end portion coupled to the tip end portion of the first oscillation body, and causes the first connector to operate, via the first oscillation body;
a second driver that extends along the first axis, includes a base end portion coupled to the tip end portion of the second oscillation body, and causes the first connector to operate, via the second oscillation body;
a support extending in the direction intersecting the first axis; and
a second connector that oscillatably connects the first oscillation body and the second oscillation body to the support, and
the third oscillator includes:
a first assister that causes the support of the first oscillator and the support of the second oscillator to operate, by connecting the support of the first oscillator and the support of the second oscillator to one base included in a pair of bases disposed with the first axis being interposed between the pair of bases; and
a second assister that causes the support of the first oscillator and the support of the second oscillator to operate, by connecting the support of the first oscillator and the support of the second oscillator to an other base included in the pair of bases.

2. The optical reflector element according to claim 1,
wherein the first driver includes a first piezoelectric element,
the second driver includes a second piezoelectric element,
the first assister includes:
a first assister body extending continuously from the one base to the support of the first oscillator and the support of the second oscillator; and
a third piezoelectric element stacked on substantially an entire surface of the first assister body, and
the second assister includes:
a second assister body extending continuously from the other base to the support of the first oscillator and the support of the second oscillator; and
a fourth piezoelectric element stacked on substantially an entire surface of the second assister body.

3. The optical reflector element according to claim 2,
wherein the first oscillation body includes a fifth piezoelectric element, and
the second oscillation body includes a sixth piezoelectric element.

4. The optical reflector element according to claim 2,
wherein the first piezoelectric element is disposed at a position including an inflection point that occurs in an entirety of the first driver and the first oscillation body during oscillation, and
the second piezoelectric element is disposed at a position including an inflection point that occurs in an entirety of the second driver and the second oscillation body during oscillation.

5. The optical reflector element according to claim 1,
wherein an entire length of the first driver is longer than an entire length of the first oscillation body, and an entire length of the second driver is longer than an entire length of the second oscillation body.

6. The optical reflector element according to claim 1,
wherein the first connector of each of the first oscillator and the second oscillator is in a shape in which an odd number of nodes occur when the first oscillator and the second oscillator are oscillated in a same direction.

7. A light control system comprising:
the optical reflector element according to claim 1; and
a control device that controls the optical reflector element,
wherein the control device oscillates the first driver and the second driver of the first oscillator, the first driver and the second driver of the second oscillator, and the first assister and the second assister of the third oscillator to rotationally oscillate the first oscillator and the second oscillator in a same direction around the first axis.

8. The light control system according to claim 7,
wherein, when the control device is to rotationally oscillate the first oscillator and the second oscillator in the same direction around the first axis, the control device:
oscillates the first driver and the second driver of the first oscillator to cause each of the first driver and the second driver of the first oscillator to have a first portion and a second portion whose directions of oscillation in a thickness direction of the optical reflector element are opposite; and
oscillates the first driver and the second driver of the second oscillator to cause each of the first driver and the second driver of the second oscillator to have a third portion and a fourth portion whose directions of oscillation in the thickness direction are opposite.

9. An optical reflector element that reciprocates light by reflecting the light, the optical reflector element comprising:
a reflector that reflects the light;
a primary oscillator for oscillating the reflector and aligned with the reflector along a first axis;
a first connector for transmitting oscillation of the primary oscillator to the reflector, the first connector being disposed along the first axis and including a base end portion; and
a secondary oscillator for oscillating the primary oscillator,
wherein the primary oscillator includes:
a first oscillation body that extends in a direction intersecting the first axis, includes a tip end portion, and is coupled to the base end portion of the first connector;
a second oscillation body that extends in the direction intersecting the first axis, includes a tip end portion, and is coupled to the base end portion of the first connector, the second oscillation body being disposed on an opposite side of the first axis from the first oscillation body;
a first driver that extends along the first axis, includes a base end portion coupled to the tip end portion of the first oscillation body, and causes the first connector to operate, via the first oscillation body;
a second driver that extends along the first axis, includes a base end portion coupled to the tip end portion of the second oscillation body, and causes the first connector to operate, via the second oscillation body; and
a second connector that oscillatably connects the first oscillation body and the second oscillation body to a support of the secondary oscillator, and
the secondary oscillator includes:
the support extending in the direction intersecting the first axis;
a pair of bases;
a first assister that causes the support to operate, by connecting the support to one base included in the pair of bases; and
a second assister that causes the support to operate, by connecting the support to an other base included in the pair of bases.

10. The optical reflector element according to claim 9,
wherein a resonance frequency of the primary oscillator and a resonance frequency of the secondary oscillator are identical.

11. The optical reflector element according to claim 10,
wherein a resonance frequency of a structure body coupling the primary oscillator and the secondary oscillator and a resonance frequency of a structure body coupling the reflector and the first connector are identical.

12. The optical reflector element according to claim 9,
wherein the first driver includes a first piezoelectric element, the second driver includes a second piezoelectric element, the first assister includes:
a first assister body extending continuously from the one base to the support; and
a third piezoelectric element stacked on substantially an entire surface of the first assister body, and
the second assister includes:
a second assister body extending continuously from the other base to the support; and
a fourth piezoelectric element stacked on substantially an entire surface of the second assister body.

13. The optical reflector element according to claim 12,
wherein the first oscillation body includes a fifth piezoelectric element, and
the second oscillation body includes a sixth piezoelectric element.

14. The optical reflector element according to claim 12,
wherein the first piezoelectric element is disposed at a position including an inflection point that occurs in an entirety of the first driver and the first oscillation body during oscillation, and
the second piezoelectric element is disposed at a position including an inflection point that occurs in an entirety of the second driver and the second oscillation body during oscillation.

15. The optical reflector element according to claim 9,
wherein an entire length of the first driver is longer than an entire length of the first oscillation body, and an entire length of the second driver is longer than an entire length of the second oscillation body.

16. The optical reflector element according to claim 9,
wherein the first connector of the primary oscillator is in a shape in which an odd number of nodes occur when the primary oscillator is oscillated.

17. A light control system comprising:
the optical reflector element according to claim 9; and
a control device that controls the optical reflector element,
wherein the control device oscillates the first driver and the second driver of the primary oscillator and the first assister and the second assister of the secondary oscillator to rotationally oscillate the primary oscillator around the first axis.

18. The light control system according to claim 17,
wherein, when the control device is to rotationally oscillate the primary oscillator around the first axis,
the control device oscillates the first driver and the second driver of the primary oscillator to cause each of the first driver and the second driver of the primary oscillator to have a first portion and a second portion whose directions of oscillation in a thickness direction of the optical reflector element are opposite.
